(19) United States
(12) Patent Application Publication
(10) Pub. No.: US 2025/0140529 A1
(43) Pub. Date: May 1, 2025

(54) ETCH UNIFORMITY IMPROVEMENT IN RADICAL ETCH USING CONFINEMENT RING

(71) Applicant: Lam Research Corporation, Fremont, CA (US)

(72) Inventors: Andreas Fischer, Castro Valley, CA (US); Gnanamani Amburose, Fremont, CA (US); Julien Monbeig, Hillsboro, OR (US)

(21) Appl. No.: 18/835,328

(22) PCT Filed: Dec. 19, 2022
(86) PCT No.: PCT/US2022/053429

§ 371 Date: Aug. 1, 2024

Related U.S. Application Data
(60) Provisional application No. 63/308,395, filed on Feb. 9, 2022.

(51) Int. Cl. H01J 37/32; H01L 21/683

(52) U.S. Cl. CPC H01J 37/32623; H01J 2237/2007; H01L 21/6831

(57) ABSTRACT

A confinement ring for use in a process chamber includes a tubular extension that is configured to surrounds a process region in the process chamber. An upper end of the tubular extension is configured to connect to a showerhead of the process chamber and a lower end that is configured to extend into the process region and proximate to an edge ring that surrounds a wafer received within the process region. A foot extension has an inner end that joins to the lower end of the tubular extension and extends outwardly from the process region to the outer end. The foot extension provides an annular surface that is configured to form a gap with a top surface of the edge ring.

### BACKGROUND

### 1. Field of the Invention

The present embodiments relate to components usable in semiconductor process chambers for controlling radicals, and more particularly, to a confinement ring to improve etch rate uniformity on the surface of a wafer.

### 2. Description of the Related Art

A semiconductor wafer is exposed to various fabrication processes to generate electronic devices. The processes that are used to generate electronic devices include deposition processes, etching processes, patterning processes, among others. An etching process is conducted in a process chamber (also referred to as an ‘etcher’). In radical etching, ions or radicals of relatively low energy are generated in plasma and directed over a surface of a substrate received on a grounded electrode. Excess radicals and process gas(es) are then removed from the etcher via exhaust ports.

In certain Radical Etch chambers, tests were conducted and certain non-uniformities in etching were measured. Data collected from the testing and experiments shows that etch rates tends to decrease gradually from the center of the wafer toward the wafer edge, and then, near the wafer edge, the etch rate increases significantly. Since costs of fabricating semiconductor devices are significant, chip designers generally want to increase semiconductor device densities all the way to the wafer edge. Etch non-uniformities near the wafer edge may cause yield loss near the wafer edge as the semiconductor devices fabricated near the wafer edge show etch-induced device performance degradation.

It is in this context that embodiments of the inventions arise.

### SUMMARY

Various implementations of the disclosure include apparatuses and systems used for confining plasma radicals within a process region of a process chamber. During an etching process (e.g., dry etching), plasma is generated in the process chamber by ionizing process gas(es) via a high-frequency electromagnetic field. In the process chamber, the generated plasma is directed over a surface of a wafer. Plasma is generated either locally within the process region defined within a process chamber or remotely outside of the process region. The generated plasma includes ions, electrons and radicals. When plasma is generated remotely, radicals from the plasma are supplied to the process region either through a showerhead or through nozzles or other delivery mechanisms.

In one embodiment, a confinement ring is used in the process chamber to confine plasma radicals substantially over the surface of the wafer. The confinement ring includes foot extensions disposed along a periphery portion of the wafer, e.g., approximately over an edge ring that surrounds the edge of the wafer. A separation between the foot extensions and the edge ring can be configured to control exhaust flow of radicals and process gas(es) out of the process region. As will be described in greater detail below, this control of flow is used to affect the velocity of radicals near the edge of the wafer so as to improve etch rate uniformity near the wafer edge.

In one embodiment, the confinement ring is coupled to a bottom surface of the showerhead. The confinement ring includes a tubular extension that extends down from the showerhead and surrounds the process region. The foot extension may be integrally formed at a lower end of the tubular extension. In one configuration, the tubular extension forms a wall that surrounds the process region. In some implementations, the tubular extension may align with the edge of the wafer received in the process chamber. In some implementations, the tubular extension may extend perpendicular to the bottom surface of the showerhead. In some implementations, the tubular extension may be slanted inwardly or outwardly from the axis perpendicular to the bottom surface of the showerhead. In some implementations, the foot extension is generally horizontal and parallel to the surface of the wafer received in the process chamber. In some implementations, the foot extension may be sloped such that it is not parallel to the surface of the wafer received in the process chamber. The foot extension may have a width that is similar to a width of an edge ring that surrounds a wafer support surface.

The observed etch rate non-uniformity at the wafer edge may be caused by back diffusion of reaction by-products from the edge ring to the edge of the wafer. Back diffusion leads to an increased concentration of unwanted plasma radicals at the wafer edge. The confinement ring disclosed herein is designed to reduce said back diffusion and, with it, the concentration of unwanted plasma radicals at the wafer edge. Additionally, the increased concentration of plasma radicals at the wafer edge may be due to the edge ring material. Typically, the edge ring is made of a material (e.g., such as aluminum oxide) that does not consume fluorine in plasma radicals as much as the surface of the wafer that is adjacent to the edge ring. This lack of fluorine consumption by the edge ring due to the difference in materials can contribute to a build-up (i.e., increased concentration) of fluorine-containing plasma radicals at the wafer edge.

In one embodiment, a confinement ring for use in a process chamber, is disclosed. The confinement ring includes a tubular extension and a foot extension. The tubular extension is configured to surround a process region defined in the process chamber and extends between its upper end and lower end. The upper end connects to a showerhead of the process chamber. The tubular extension extends down from the upper end such that the lower end is proximate to an edge ring that surrounds a wafer receiving surface. The foot extension extends between its inner end and outer end, the latter of which defines an outer diameter of the confinement ring. The inner end joins to the lower end of the tubular extension and the outer end extends outwardly from the process region. The foot extension provides a confining annular surface that forms a gap with a top surface of the edge ring.

Other aspects and advantages of the invention will become apparent from the following detailed description, taken in conjunction with the accompanying drawings, illustrating by way of example the principles of the invention.

### BRIEF DESCRIPTION OF THE DRAWINGS

FIG. 1A illustrates a side, cross-sectional view of a process chamber used to perform an etching operation using radical etching, the process chamber employs a confinement ring and is shown in an active state (i.e., process-ready state), in one embodiment.

FIG. 1B illustrates a side, cross-sectional view of a process chamber of FIG. 1A with the process chamber shown in an inactive state.

FIG. 1C illustrates a side, cross-sectional view of a process chamber of FIG. 1A with the process chamber shown in an active state for use to perform a waferless auto clean (WAC) operation, in one embodiment.

FIG. 2A illustrates a vertical cross-sectional view of a portion of a showerhead with a confinement ring coupled thereon, in one embodiment.

FIG. 2B illustrates a profile of the confinement ring shown in FIG. 2A, in an alternate embodiment.

FIG. 2C illustrates a profile of the confinement ring shown in FIG. 2A, in another alternate embodiment.

FIG. 2D illustrates a profile of the confinement ring shown in FIG. 2A, in another alternate embodiment.

FIG. 2E illustrates a profile of the confinement ring shown in FIG. 2A, in another alternate embodiment.

FIG. 2F illustrates a profile of the confinement ring shown in FIG. 2A, in yet another alternate embodiment.

FIG. 2G illustrates a profile of the confinement ring shown in FIG. 2A, in yet another alternate embodiment.

FIG. 3 illustrates a graph detailing the etch rate from a center of a wafer to an edge of the wafer when the confinement ring with a foot extension is used to confine plasma in a process region of the process chamber, as a function of different gap distances, in one embodiment.

### DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

Implementations of the disclosure provide various details of a confinement ring and a system that that uses the confinement ring for processing semiconductor substrates (i.e., wafers). It should be appreciated that the present embodiments can be implemented in numerous ways, such as a process, an apparatus, a system, a device, or a method. Several examples of implementations are described below.

A confinement ring used in a process chamber to confine radicals within a process region is disclosed herein. The confinement ring is designed to control the flow and exhaust of radicals and other gas(es) out of a process region during an etching operation. In one embodiment, the confinement ring employed in the process chamber is used to reduce radicals concentration over edge regions of the wafer. In one example, the confinement ring is coupled to a bottom surface of a showerhead disposed in an upper portion of the process chamber. In one configuration, the showerhead discussed herein is used to induce collisions of ions with the showerhead hardware thereby neutralizing them but allowing radicals to flow to the process region.

In some implementations, the confinement ring includes a tubular extension and a foot extension. The tubular extension has a length and hangs down from the showerhead and surrounds part of the process region in the process chamber. The foot extension may be integrally connected to a lower end of the tubular extension and extends outward, away from the process region. The foot extension forms an annular surface that enables control of a separation between the foot extension and the edge ring. In operation, the separation between the foot extension and the edge ring enables control of the velocity at which radicals and other gas(es) flow out of the process region. This control enables reduction of back diffusion of by-products stemming from the etching on the surface of the edge ring, thereby reducing the concentration gradients of radicals at the wafer edge and correspondingly increases etch rate uniformity at the wafer edge (e.g., outer 20 mm of a 300 mm wafer).

According to some implementations, the foot extension of the confinement ring is designed to create a narrow gap between the edge ring and the foot extension. The gap provides a path for radicals to exit the process region and flow toward an exhaust port provided in the lower portion of the process chamber. In some implementations, the gap is sufficiently narrow to cause radicals exiting the process region to increase in velocity as they flow toward the exhaust port. Speed of radical removal from the process region impacts the concentration gradient of radicals over the wafer edge. By increasing the radical exit velocity, concentration of unwanted radicals near the wafer edge is reduced, thereby achieving a better etch rate uniformity at the wafer edge. Thus, by varying the dimensions and/or shape of the foot extension of the confinement ring, the profiles of the gap between the edge ring and the foot extension can be adjusted and the radical exit velocity and ultimately the etch rate can be controlled to increase the etch rate uniformity across the whole wafer.

The various features of the confinement ring will now be discussed with reference to the drawings.

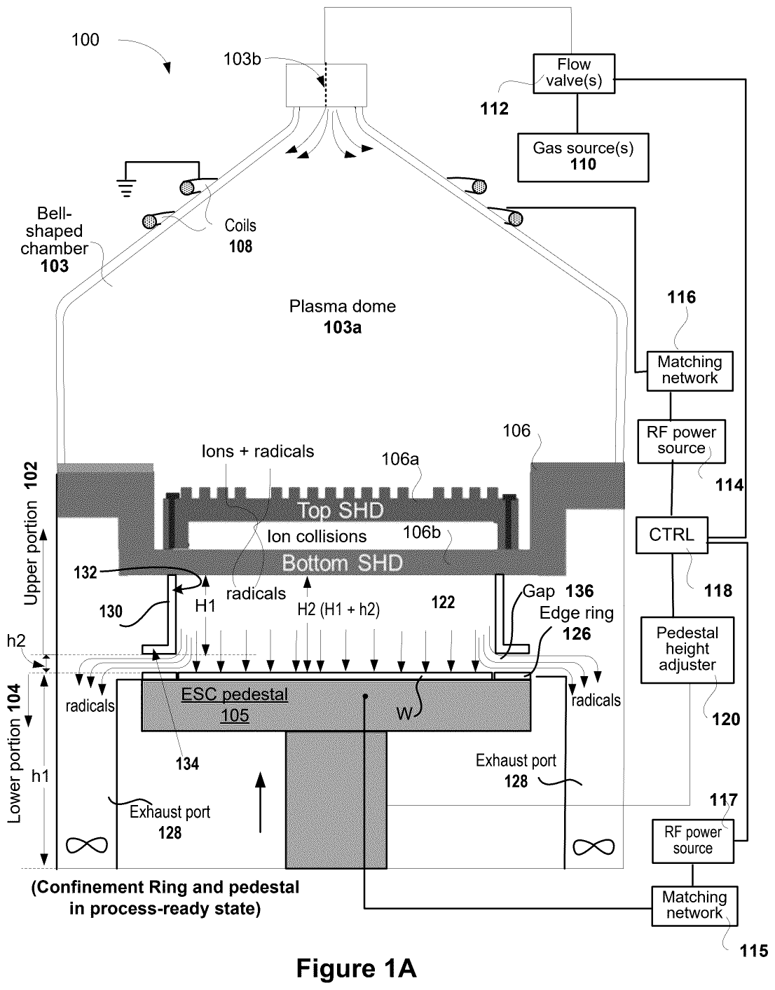

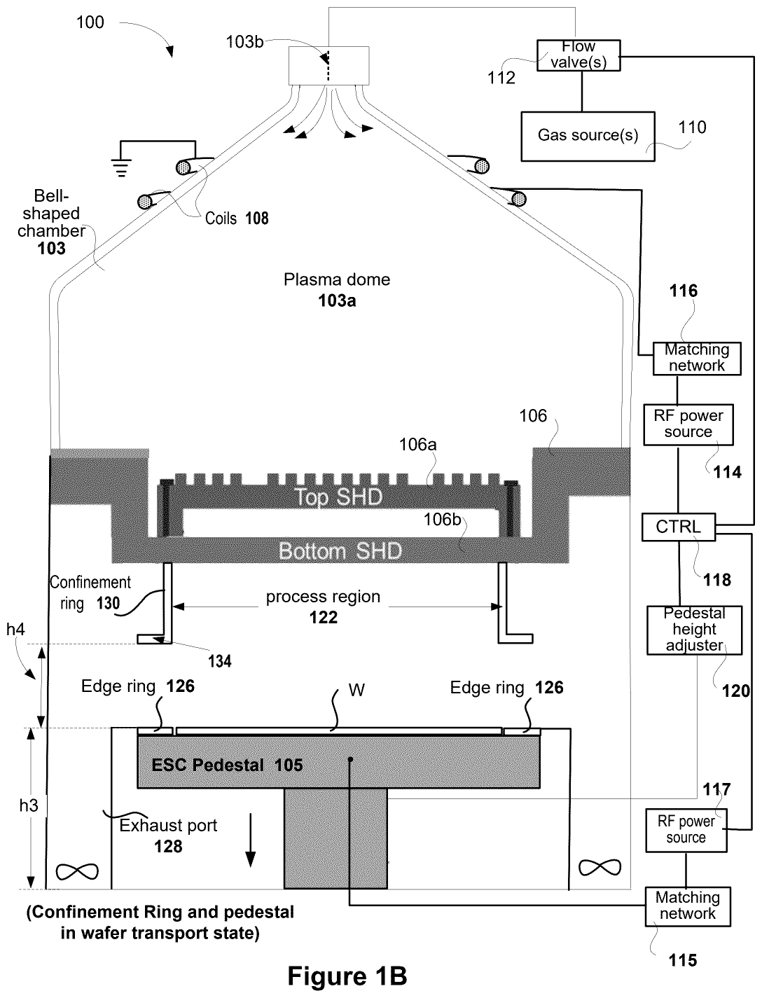

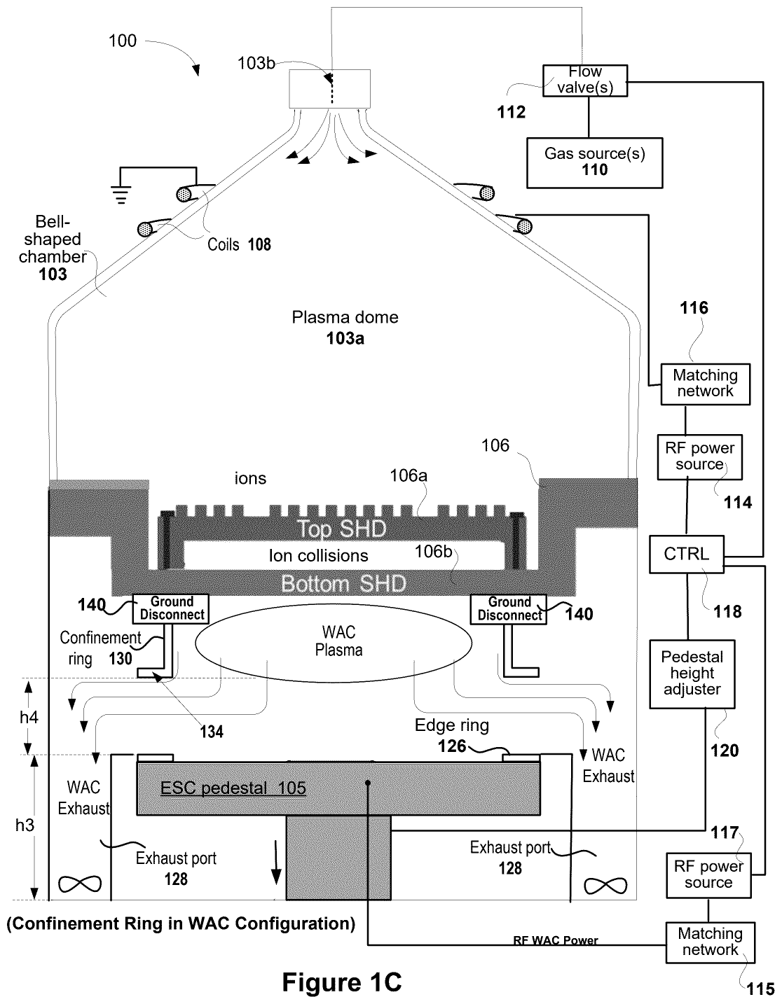

FIG. 1A is a simplified view of a process chamber 100 used for processing a wafer ‘W’, in accordance with some implementations of the invention. In some implementations, the process chamber 100 is a single station chamber, in that a single wafer is processed at any given time. The process chamber 100 includes an upper portion 102 that houses an inner chamber 103 and a lower portion 104 that houses a pedestal 105. The inner chamber 103 includes a plasma dome 103a. An opening 103b is defined at the top of the plasma dome 103a. The opening 103b is used to supply process gas(es) from one or more gas sources 110 for generating plasma. The upper portion 102 of the process chamber 100 includes a showerhead 106. The showerhead 106 is used to flow process gas(es) and radicals into a process region 122 and to neutralize ions via collisions within the showerhead 106 before they enter the process region 122. The ion collisions generally occur at a top showerhead 106a and at a bottom showerhead 106b as the top showerhead 106a and the bottom showerhead 106b are arranged in a non-line-of-sight (i.e., non-linear) orientation relative to each other. The flow of process gas(es) supplied to the inner chamber 103 may be regulated using one or more flow valves 112 that are coupled to the gas source(s) 110.

In one embodiment, a first end of a coil 108 is coupled to a power source, such as a radio frequency (RF) power source (e.g., first RF power source) 114, and a second end of the coil 108 is connected to ground. The coil 108 provides RF power to the process gas(es) received in the plasma dome 103a of the inner chamber 103 to generate plasma. As shown, a matching network 116 is provided to couple RF power from the RF power source 114 to the coil 108 efficiently. The RF power source 114 is coupled to a controller 118, which is used to control the RF power supplied to the coil 108.

Inlets are provided in the top showerhead 106a to supply radicals and ions from plasma

generated in the plasma dome 103a to the bottom showerhead 106b. In some implementations, the top showerhead 106a is connected to the bottom showerhead 106b using e.g., fasteners, connectors, screws, O-rings, or the like. In other implementations, the top and the bottom showerheads (106a, 106b) are manufactured from one piece of metal. The lower portion 104 of the process chamber 100 includes a pedestal 105. In some implementations, the pedestal is an electrostatic chuck (ESC). A top surface of the ESC pedestal (or simply referred to henceforth as “ESC”) 105 includes a wafer receiving surface (not shown). The wafer is received on the wafer receiving surface for processing. An edge ring 126 is disposed adjacent to and surrounds the wafer received on the wafer receiving surface. The ESC 105 is coupled to a power source, such as a second RF power source 117 through a corresponding matching network (i.e., second matching network) 115. The ESC 105 is coupled to a pedestal height adjuster 120 to allow the ESC 105 to be moved vertically up or down. The pedestal height adjuster 120, in turn, is coupled to the controller 118. The pedestal height adjuster 120 uses signals from the controller 118 to adjust the height of the ESC 105. A confinement ring 130 is disposed below the bottom showerhead 106b and is used to surround a process region 122 defined in the process chamber 100.

In one embodiment, the pedestal height adjuster 120 can change the height of the ESC 105 so that the ESC 105 is closer or further from a bottom surface of a foot extension 134 of a confinement ring 130. This height adjustment therefore enables adjusting a gap (i.e., a separation distance) between the bottom surface of the foot extension 134 and the top surface of the edge ring 126 that is positioned on a top surface of the ESC 105. For example, in FIG. 1A, the ESC 105 is at a height ‘h1’, which places the separation between the bottom surface of the foot extension 134 and the top surface of the edge ring 126 at a height (or a separation distance) ‘h2’. This position may be referred to as an operational position where etching is conducted. The foot extension 134 of the confinement ring 130 therefore enables a modification of the velocity at which radicals and other gas(es) are removed from the process region 122. By way of example, when the separation (h2) is reduced further but is greater than zero, the velocity at which radicals are removed from the process region 122 is increased near the wafer edge. The velocity at which radicals are removed from the process region 122 can be tuned by changing the separation (h2) distance to be greater than zero. Generally, smaller the separation h2, faster the exit velocity, and therefore, lower the concentration of unwanted radicals near the wafer edge. In these implementations, the confinement ring 130 may be hard-mounted to the upper portion of the process chamber. In other implementations, the confinement ring 130 may be mounted to the upper portion of the process chamber using fasteners, connectors, screws, O-rings, or the like. In yet other implementations, the confinement ring 130 may be mounted to the upper portion of the process chamber using adjustable mounts. For example, the confinement ring 130 is mounted either to the bottom showerhead 106b or to a structure next to the showerhead 106. In some implementations, the structure next to the showerhead 106 may be a top plate (not shown).

In some implementations, the separation (h2) between the bottom surface of the foot extension 134 and the top surface of the edge ring 126 can be controlled by lowering or raising the confinement ring 130. The confinement ring 130 mounted to or next to the showerhead 106 is coupled to a motor (not shown) and the motor, in turn, is coupled to the controller 118. A signal from the controller 118 is used to adjust the position of the confinement ring 130, which drives the separation. In various implementations, only the confinement ring 130 adjustably mounted to the upper portion of the process chamber is moved to adjust the separation, only the showerhead 106 with the mounted confinement ring 130 is moved to adjust the separation, only the ESC 105 is moved to adjust the separation, both the confinement ring 130 adjustably mounted to the upper portion of the process chamber and the ESC 105 are moved to adjust the separation, or both the showerhead 106 with the mounted confinement ring 130 and the ESC 105 are moved to adjust the separation. Movement of the ESC 105 and the showerhead 106 with the mounted confinement ring 130 can be independently or jointly controlled using signals from the controller 118.

It is believed that a concentration of radicals increases near the wafer edge because of the difference in materials seen by radicals at the wafer-to-edge ring interface. Typically, a wafer is made of silicon and may include polysilicon materials. In contrast, if an edge ring is made from a material, such as alumina (i.e., aluminum oxide) that does not consume fluorine during etching, more fluorine tends to back diffuse toward the wafer edge and is available for a secondary reaction around the edge of the wafer. As a result, it is observed that a substantial increase of back diffusion of radicals occurs at the wafer edge, which results in non-uniformities in etch. Advantageously, the confinement ring 130 of the present disclosure can be configured to prevent back diffusion of radicals by increasing their exit velocity from the process region 122 near the wafer edge. As shown in FIG. 1A, the illustrative flow lines show how radicals will have an increased velocity exiting the process region 122 via a gap 136 of height h2 defined between the foot extension 134 and the edge ring 126.

Still referring to FIG. 1A, the confinement ring 130, as noted above, is coupled to the bottom showerhead 106b and includes a tubular extension 132 that forms a sidewall that surrounds the process region 122. The foot extension 134 defines an annular surface that extends outward from a bottom of the tubular extension 132 and away from the process region 122. The confinement ring 130, in some examples, is made from conductive materials, such as, for example, aluminum. In some examples, the confinement ring 130 is made from aluminum that is coated with a dielectric material. In some implementations where the ESC 105 is coupled to the second RF power source 117 through a second matching network 115, the confinement ring 130 may be made of ceramic or other insulating material, to avoid RF coupling to the confinement ring 130. As shown, the tubular extension 132 of the confinement ring 130 extends down for a height ‘H1’. As mentioned above, the ESC 105 can be moved to a position suitable for an etching operation. Also in this example, the bottom surface of the bottom showerhead 106b is at a height ‘H2’ from the top surface of a wafer. In this example, height H2 is equal to heights H1+h2 (i.e., height of the tubular extension 132 of the confinement ring 130+height of the gap 136 between the annular surface (i.e., bottom surface) of the foot extension 134 and the top surface of the edge ring 126). The gap 136 provides a passage (i.e., pathway) through which radicals and gas(es) are forced out of the process region 122 toward an exhaust port 128 defined in the lower portion 104 of the process chamber 100.

As noted, narrowing the passage causes an increase in the exit velocity of radicals exiting

the process region 122. The increase in velocity can be attributed to the process chamber 100 trying to maintain the equilibrium within the process region 122 between an inflow and an outflow of radicals and gas(es). The increase in exit velocity leads to a suppression of back diffusion of radicals and a reduction in the concentration gradient of radicals at the wafer edge.

FIG. 1B shows a simplified view of the process chamber 100 with the ESC 105 in a lowered position. In the lowered position, a wafer may be delivered to or removed from the process chamber 100. As mentioned above, the pedestal height adjuster 120 can control movement of the ESC 105 up or down, and in this case the ESC 105 is moved downward to a height h3. This position increases the gap 136 between the foot extension 134 and the edge ring 126 to height h4 (i.e., h4>h2). In some cases, the ESC 105 may be lowered to a position that is between the operational position (illustrated in FIG. 1A) and the lowered position (illustrated in FIG. 1B) to perform an etch operation or other operations.

FIG. 1C shows a cross-sectional view of the process chamber 100 where a waferless auto clean (WAC) operation is performed. In a WAC operation, radicals and ions are used to clean the inside surfaces surrounding the process region 122 of the process chamber 100. The inside surfaces surrounding the process region 122 can see an accumulation of polymers and other by-products released during etch operations. As a result, a WAC operation is periodically performed in between sessions of wafer etching. As shown, the ESC 105 is also coupled to a RF power source 117 through a corresponding matching network 115.

In some implementations, the confinement ring 130 is made of a conductive material. In such implementations, the confinement ring 130 is connected to ground to provide a RF return path to ground for the RF current from the powered ESC 105 out of the process region 122. In some implementations, a ground disconnect 140 is provided. The ground disconnect 140 is configured to disconnect the structure of the confinement ring 130 from ground, and cause the confinement ring to be electrically floating.

The ground disconnect 140 can be a switch or a mechanical element that can be moved to connect or disconnect the electrical connection. In some implementations, the ground disconnect 140 is an RF switch. When the RF connection is disconnected, mechanically the confinement ring 130 may still be connected to the showerhead 106 using a type of insulator connector. In one example, the controller 118 can set ground disconnect 140 to be RF floating or be RF connected. In one embodiment, the ground disconnect 140 may have a motor that enables mechanical movement of a switch or connector.

By RF floating the confinement ring 130, RF power will seek an alternate path to ground. The alternate path, for example, could be via the showerhead 106 or inner walls of the process chamber 100. RF floating the confinement ring 130 is not limited to WAC operations. Rather, the confinement ring 130 may be RF floating during other etch operations where RF power from the ESC 105 is needed to power the plasma in the process region 122.

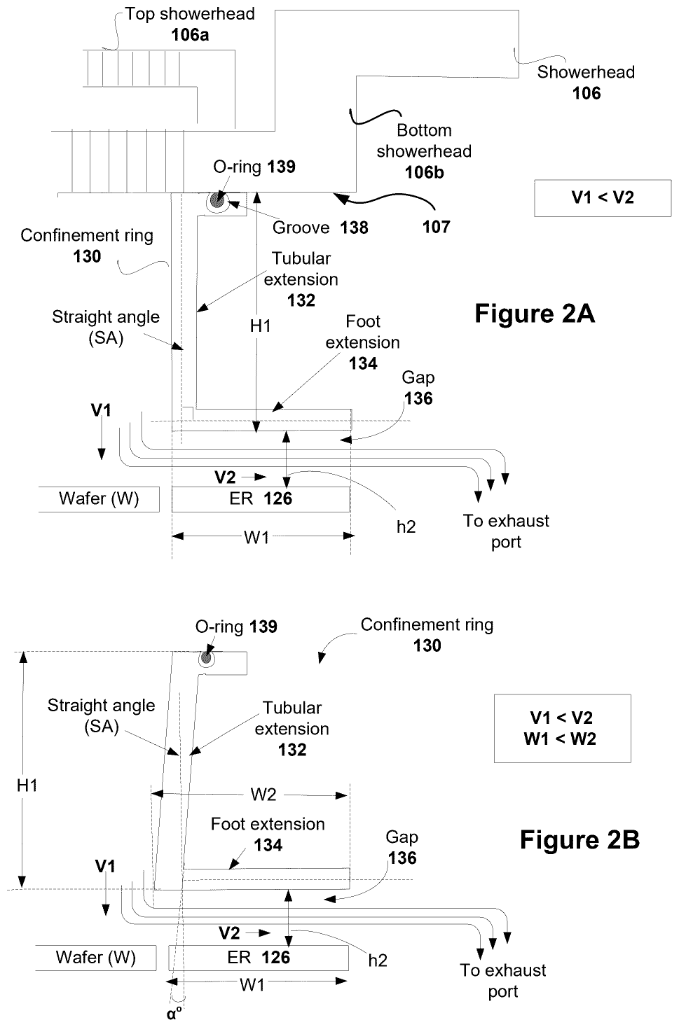

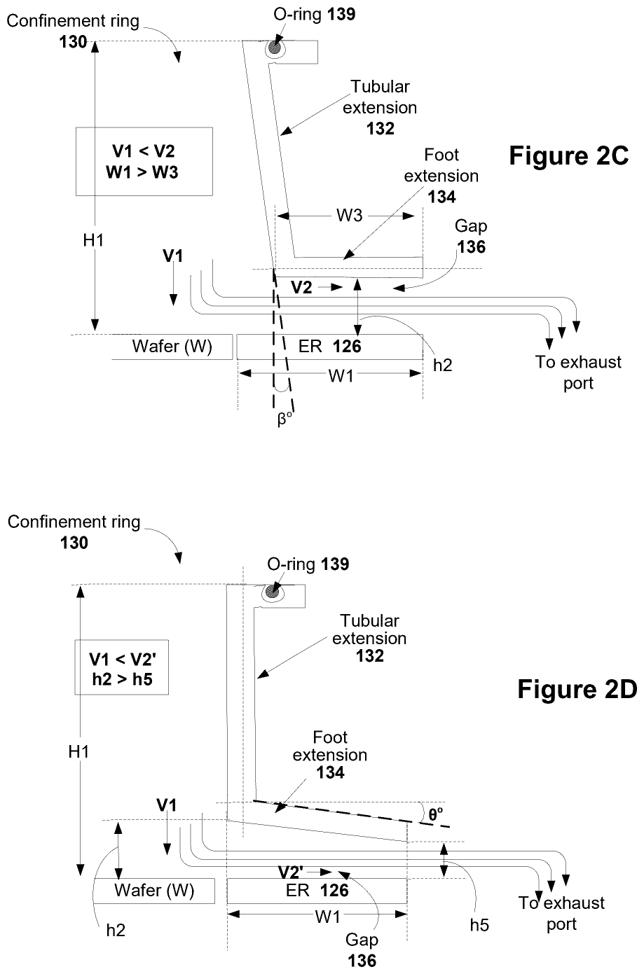

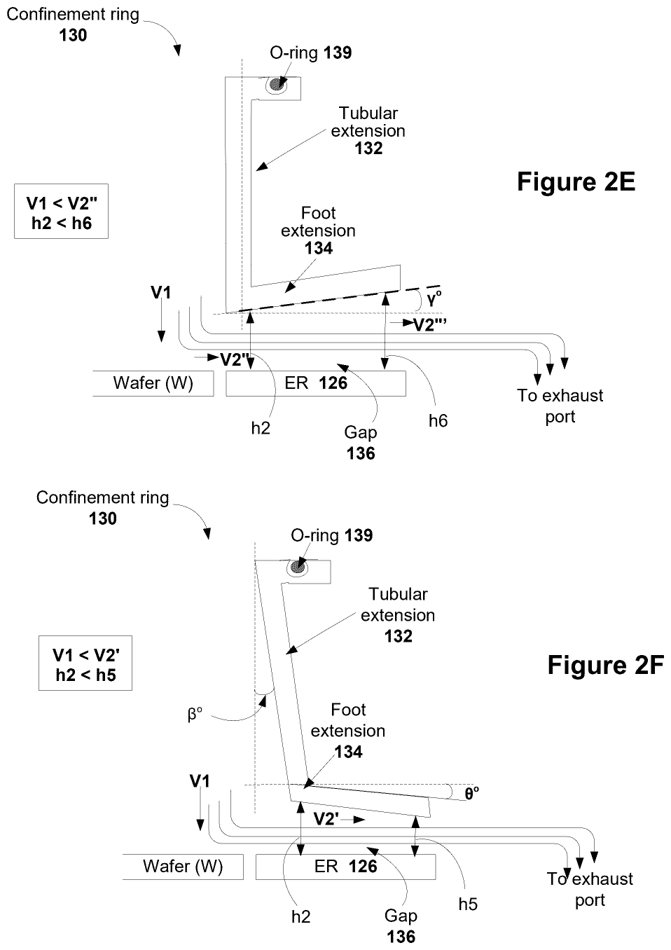

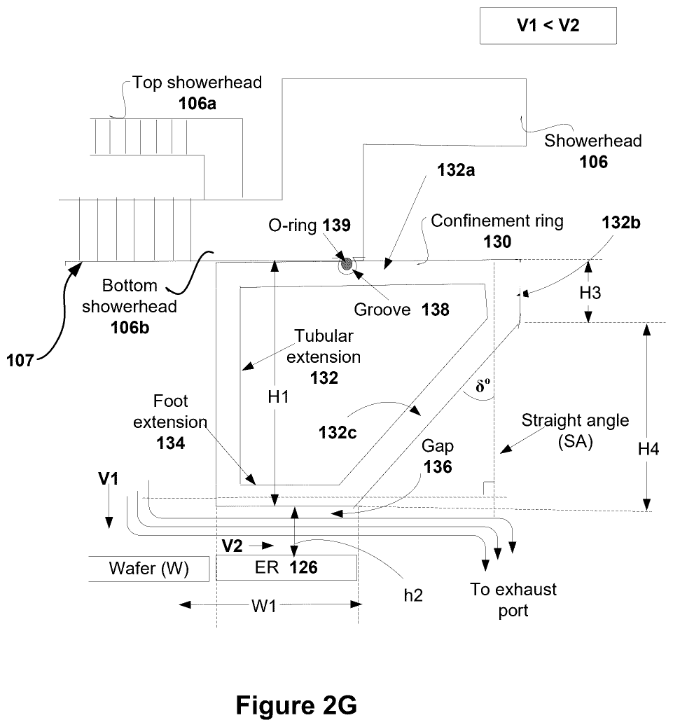

FIG. 2A illustrates an expanded cross-sectional view of the confinement ring 130 used in the process chamber 100, according to some implementations. The confinement ring 130 is configured to confine radicals and gas(es) within the process region 122 and to control removal of radicals from the process region 122. The confinement ring 130 may be coupled to the bottom showerhead 106b using fasteners, connectors, screws, or the like. In addition, an optional O-ring 139 may provide a seal between the confinement ring 130 and the bottom showerhead 106b. For example, a top surface of the confinement ring 130 includes a groove 138 into which the O-ring 139 is received. The confinement ring 130 is coupled to the bottom showerhead 106b by compressing the O-ring to seal gaps. In other embodiments, the confinement ring 130 can be coupled to a structure that is, or may expand to, outside of a radius of the showerhead 106. While not explicitly shown in the figures, in some embodiments, more than one O-ring, and/or different types of seal may be used independently, or in conjunction with one or more O-rings to seal any gaps between the confinement ring 130 and the bottom showerhead 106b.

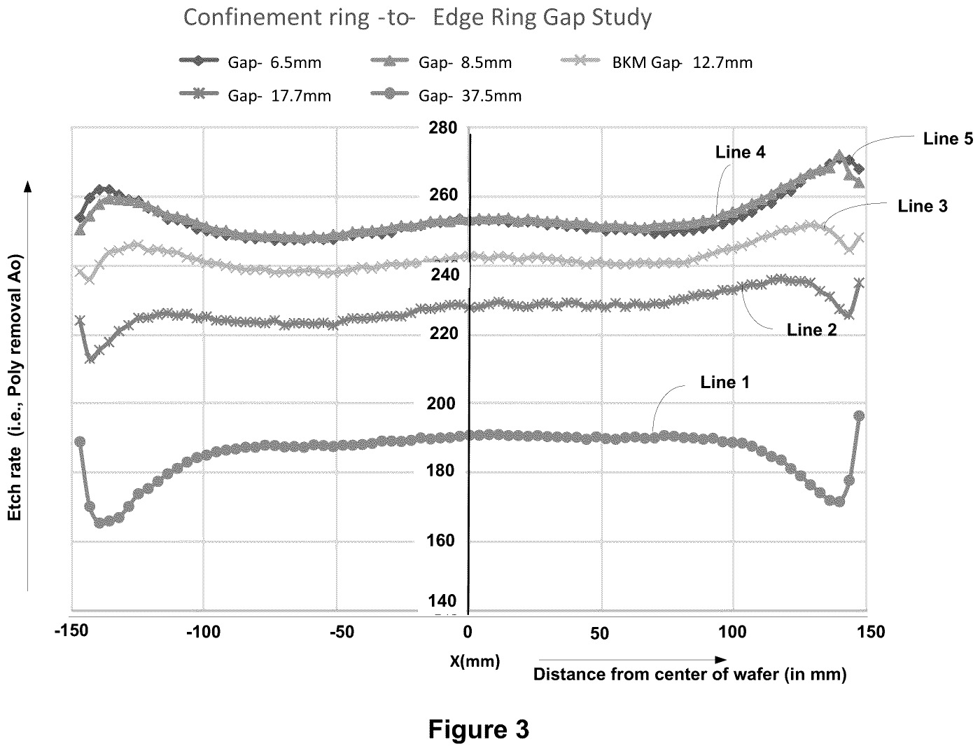

As noted above, the confinement ring 130 includes a tubular extension 132 and a foot extension 134. The tubular extension 132 extends down between its upper end and a lower end. The foot extension 134 extends between its inner end (facing the process region) and outer end (facing away from the process region). The lower end of the tubular extension 132 connects to or is otherwise integrated with the inner end of the foot extension 134. In this example, the tubular extension 132 extends at a straight angle ‘SA’ between the upper and the lower ends and is orthogonal to a bottom surface 107 of the bottom showerhead 106b. The tubular extension 132 extends for a height H1, so that the lower end is proximate to the edge ring 126 (received on the ESC 105). In some implementations, the term ‘proximate’ is defined such that a separation distance between the top surface of the edge ring 126 and the bottom surface of the foot extension 134 of the confinement ring 130 is between 1 mm and 50 mm. In some implementations, the separation distance can vary by +/−20% of the aforementioned range. In some implementations, the separation distance between the top surface of the edge ring 126 and the bottom surface of the foot extension 134 of the confinement ring 130 is defined to be about 37 mm. In alternate implementations, the separation distance between the top surface of the edge ring 126 and the bottom surface of the foot extension 134 of the confinement ring 130 is defined to be about 50 mm. Examples of the tested separation distances are discussed with reference to FIG. 3. As noted above, this is a tunable parameter that can be set depending on the process being run, gas(es) used, and other operational parameters. The foot extension 134 between the inner and the outer ends therefore defines an annular surface. The term ‘about’ is defined to include a variance of +/−15% of the specified value.

In some implementations, the tubular extension 132 is configured to align over an outer

edge of the wafer receiving surface defined on the ESC 105. The tubular extension 132 provides a sidewall that surrounds the process region 122 so that radicals and gas(es) can be substantially confined over the wafer during operation. In some implementations, the width of the annular surface of the foot extension 134 is defined to at least partially cover a width of the surface of the edge ring 126. In some implementations, the width of the annular surface of the foot extension 134 substantially covers the entire width ‘W1’ of the surface of the edge ring 126. In some implementations, the width ‘W2’ of the foot extension 134 is longer than W1 of the edge ring 126, such that when the tubular extension 132 is aligned with an outer edge of the wafer W received on the ESC 105, an outer edge of the foot extension 134 would extend beyond the width W1 of the edge ring 126 received adjacent to the outer edge of the wafer W. In some implementations, the width ‘W2’ of the foot extension 134 is longer than W1 of the edge ring 126, such that when the outer edge of the foot extension 134 is aligned with an outer edge of the edge ring 126 received adjacent to the wafer W, an inner edge of the foot extension 134 may align or overlap with the area over the edge of the wafer.

The foot extension 134, in some implementations, is defined to be orthogonal to the tubular extension 132 and the annular surface of the foot extension 134 is substantially parallel (+/−5%) to the edge ring 126. Still referring to FIG. 2A, the gap 136 defined between the annular surface of the foot extension 134 and the edge ring 126 is substantially uniform through the length of the gap 136 (i.e., the height ‘h2’ of the gap 136 along the annular width of the foot extension 134 is uniform). The passage defined by the gap 136 can be set to cause an increase in the exit velocity of radicals and gas(es) flowing out of the process region 122 from V1 to V2 (i.e., V2>V1). The height h2 of the gap 136 should also be set to ensure that the gap is not too narrow to create a bottleneck. For instance, a gap 136 that is less than about 1 mm can potentially lead to increased back diffusion of radicals into the process region 122.

FIGS. 2B-2G illustrate non-limiting examples of different profiles of the confinement ring 130 that can be used in the process chamber 100 for confining radicals and shaping the exhaust flow below the foot extension 134. FIGS. 2B, 2C, 2F and 2G illustrate different profiles of the tubular extension 132 and FIGS. 2D, 2E and 2F illustrate different profiles of the foot extension 134. Referring to FIG. 2B, the tubular extension 132 is disposed at an angle ‘α°’ relative to a straight angle ‘SA’. The tubular extension 132 extends downward and inward towards the process region 122. The angle (α°) created by the sloped tubular extension in FIG. 2B is different from the perpendicular angle relative to the bottom showerhead 106b shown in FIG. 2A.

As with the implementation of FIG. 2A, the tubular extension 132 of the confinement ring 130 illustrated in FIG. 2B extends for a height H1 between the upper end and the lower end. The foot extension 134 joins at the lower end of the tubular extension 132 so as to be substantially parallel (+/−5%) to the edge ring 126 and the bottom showerhead 106b. The lower end of the tubular extension 132 is aligned to about the outer edge of the wafer. Further, the outer end of the foot extension 134, in this implementation, aligns with an outer edge of the edge ring 126. The annular surface of the foot extension 134 defined between the inner end and the outer end extends for a width ‘W2’. Width W2 of the annular surface of the foot extension 134 is greater than the width ‘W1’ of the edge ring 126. The gap 136 defined between the annular surface of the foot extension 134 and the edge ring 126 is substantially uniform (+/−5%) and extends for a height h2. The exit velocity of radicals flowing out of the process region 122 increases from V1 to V2 (i.e., V2>V1) as it flows through the passage of the gap 136. Again, the increase velocity V2 can be tuned by setting the gap 136 to a separation that is most effective to reduce non-uniformities in etch rates at the wafer edge.

FIG. 2C illustrates an alternate confinement ring profile than what is illustrated in FIGS. 2A and 2B, in one implementation. In this implementation, the tubular extension 132 is disposed at an angle ‘β°’ relative to the straight angle. Further, the tubular extension 132 extends downward and outward away from the process region 122. The tubular extension 132 of the confinement ring 130 extends for a height H1 between its upper end and the lower end. The foot extension 134 extends from the lower end of the tubular extension 132 and is substantially parallel to the edge ring 126 and the bottom showerhead 106b.

FIG. 2D illustrates another confinement ring profile than what is illustrated in FIGS. 2A-2C, in one implementation. In FIG. 2D, the tubular extension 132 extends vertically down from its upper end to a lower end and is perpendicular to the bottom showerhead 106b. However, the foot extension 134 extends downwardly at an angle that is different from a perpendicular angle in relation to the tubular extension 132.

In FIG. 2D, the foot extension 134 extends down from the inner end to the outer end of the confinement ring 130 at a taper angle θ° relative to the perpendicular angle. The tubular extension 132 aligns with an inner edge of the edge ring 126 and the outer end of the foot extension 134 aligns with the outer edge of the edge ring 126. The height of the tubular extension 132 of the confinement ring 130 between its upper end and the lower end is H1 and the width of the annular surface of the foot extension 134 is equal to the width ‘W1’ of the edge ring 126. In some implementations, the outer end of the foot extension 134 may extend for a width that is longer or shorter than the outer edge of the edge ring 126. Due to the downward slope of the foot extension 134 from the tubular extension 132, the height of the gap 136 between the annular surface of the foot extension 134 and the edge ring 126 is not uniform (i.e., can vary) across the width of the foot extension 134. Instead, the height of the gap 136 progressively decreases from height h2 at the inner end of the foot extension 134 to height ‘h5’ at the outer end of the foot extension 134, wherein h2>h5. Due to further narrowing of the gap 136 at the outer end of the foot extension 134, the radicals and other gas(es) flowing through the gap 136 accelerate toward the exhaust port 128 causing the exit velocity to increase in velocity from V1 (i.e., velocity measured before the radicals enter the gap 136) to V2′ (i.e., V2′>V1) (i.e., velocity measured as the radicals exit the gap 136). By way of example, exit velocity V2′ may be greater than exit velocity V2 of FIGS. 2A-2C. While not explicitly shown in the figures, in some embodiments, a top surface or the edge ring 126 may be sloped with the thickness of the inner diameter greater than the thickness of the outer diameter. In such embodiments, the difference between h2 and h5 would be smaller, compared to what is shown in FIG. 2D. In some such instances, h2 would be substantially equal to h5.

FIG. 2E illustrates yet another confinement ring profile than what is illustrated in FIGS. 2A-2D. As with FIG. 2D, the tubular extension 132, in this implementation, extends vertically down from an upper end to a lower end and is substantially perpendicular (+/−5%) to the bottom showerhead 106b. The foot extension 134 is inclined up from the inner end to the outer end at a taper angle γ° in relation to the perpendicular angle. The tubular extension 132 and the inner end of the foot extension 134 align with an inner edge of the edge ring 126 and the outer end of the foot extension 134 aligns with the outer edge of the edge ring 126. The height of the tubular extension 132 of the confinement ring 130 between the upper end and the lower end is H1 and the width of the annular surface of the foot extension 134 is equal to the width ‘W1’ of the edge ring 126. Due to the upward and outward slope of the foot extension 134 toward the outer end, the height of the gap 136 between the annular surface of the foot extension 134 and the edge ring 126 is not uniform across the width of the foot extension 134. Instead, the height of the gap 136 progressively increases from height h2 at the inner end of the foot extension 134 to height ‘h6’ at the outer end of the foot extension 134, wherein h6>h2.

The edge ring 126 is disposed such that the top surface of the edge ring 126 is co-planar with the top surface of the wafer W. The passage defined by the gap 136, the height of which increases from the inner end to the outer end of the foot extension 134 is set to cause an increase in the exit velocity of the radicals and gas(es) flowing out of the process region 122 from V1 (i.e., velocity of the radicals before the radicals enter the gap 136) to V2″ (i.e., V2″>V1) (i.e., velocity measured as the radicals pass through the narrow inner end of the gap 136). However, the exit velocity decreases in velocity from V2″ at the inner end to V2′″ at the outer end of the gap 136. The decrease in exit velocity can be attributed to increase in the height of the gap 136 toward the outer end. The exit velocity V2′″ is still greater than exit velocity V1 in the process region 122 but is less than exit velocity V2 of FIGS. 2A-2C and V2′ of FIG. 2D.

FIG. 2F illustrates another confinement ring profile than what is illustrated in FIGS. 2A-2E, in an alternate implementation. The tubular extension 132, in this implementation, extends at an angle (β°) from an upper end to a lower end that is different from a perpendicular angle (+/−5%) relative to the bottom surface 107 of the bottom showerhead 106b. The angle of outward slope of the tubular extension 132 is shown to be similar to what is shown in FIG. 2C. In some implementations, the angle of the outward slope of the tubular extension 132 can be greater than or less than β°. In addition to the outward slope of the tubular extension 132, the foot extension 134 is also shown to be sloped downwardly from an inner end to an outer end at a taper angle θ°. The angle of downward slope of the foot extension 134 is shown to be similar to what is shown in FIG. 2D.

In alternate implementations, the angle of the downward slope of the foot extension 134 can be greater than or less than θ° in relation to the perpendicular angle. The tubular extension 132 aligns with an inner edge of the edge ring 126 at its upper end and the outer end of the foot extension 134 aligns with the outer edge of the edge ring 126. The height of the tubular extension 132 of the confinement ring 130 between the upper end and the lower end is H1 and the width of the annular surface of the foot extension 134 is equal to the width ‘W1’ of the edge ring 126. Due to the downward slope of the foot extension 134 from the tubular extension 132 outward, the height of the gap 136 between the annular surface of the foot extension 134 and the edge ring 126 is not uniform across the width of the foot extension 134. Instead, the height of the gap progressively decreases from height h2 at the inner end of the foot extension 134 to height ‘h5’ at the outer end of the foot extension 134, wherein h2>h5. The edge ring 126 is disposed such that the top surface of the edge ring 126 is co-planar with the top surface of the wafer W. Due to further narrowing of the gap 136 from the inner end to the outer end of the foot extension 134, the radicals flowing through the gap 136 accelerate as they pass through the initial narrow end of the gap 136 toward the exhaust port 128 causing an increase in exit velocity from V1 (i.e., velocity measured before the radicals enter the gap 136) to V2′ (i.e., velocity measured as the radicals exit the gap 136), where V2′>V1. While not explicitly shown in the figures, in some embodiments, a top surface or the edge ring 126 may be sloped with the thickness of the inner diameter greater than the thickness of the outer diameter. In such embodiments, the difference between h2 and h5 in FIG. 2F would be smaller. In some such instances, h2 would be substantially equal to h5.

FIG. 2G illustrates another alternate confinement ring profile, in one implementation. The confinement ring 130, in this implementation, includes a plurality of segments. For instance, the confinement ring 130 includes the tubular extension 132, a first segment 132a, a second segment 132b, a third segment 132c and the foot extension 134. The tubular extension 132 of the confinement ring 130 extends vertically down from its upper end to a lower end. The first segment 132a extends along a horizontal axis at the upper end and is used to couple the confinement ring 130 to the bottom showerhead 106b. The first segment 132a extends outward and away from the process region 122. The second segment 132b extends down orthogonal to the first segment 132a for a height ‘H3’ from the upper end. The third segment 132c extends down for a height ‘H4’ from a bottom of the second segment 132b to the outer end of the foot extension 134. In some implementations, the third segment 132c extends downward and inward at an angle ‘δ°’ relative to the straight angle. The foot extension 134 extends for a width W1 between the inner end and the outer end.

In some implementations, the confinement ring 130 has a different design (not shown) than what is shown in FIG. 2G. In such implementations, the plurality of segments of the confinement ring 130 includes a first segment 132a, a second segment 132b, a third segment 132c and the foot extension 134, wherein the first, the second and the third segments (132a, 132b, 132c) together define the tubular extension 132. The location and orientation of the first, the second, the third segments (132a, 132b, 132c) and that of the foot extension 134 are similar to what is shown in FIG. 2G. The design of the confinement ring 130 in these implementations vary from the design of the confinement ring 130 shown in FIG. 2G, in that the confinement ring 130 of FIG. 2G includes an additional tubular extension 132 that extends vertically down from the bottom surface 107 of the bottom showerhead 106b.

The various confinement ring profiles have been provided as mere examples and that other profiles, such as the tubular extension 132, including the first, the second, and the third segments (132a, 132b, 132c) as a whole or in part, extending downward and outward away from the process region 122 or extending downward and inward into the process region 122 and the foot extension 134 extending upward or downward from the inner end to the outer end can also be envisioned. Further, the angles of upward/downward/outward/inward slopes of the tubular extension 132, including the first, the second and the third segments (132a, 132b, 132c) and the foot extension 134 have been provided as examples and are not limiting to the implementations of the present disclosure. It should be noted that the thickness of the tubular extension, including the first, the second, and the third segments (132a, 132b, 132c) and/or the foot extension 134 can vary across the length or width of the respective component and does not have to be uniform. Further, where a slope exists in any component (i.e., tubular extension 132, including first, second and third segments (132a, 132b, 132c) and/or the foot extension 134) of the confinement ring 132, the slope need not have to be constant but can vary along the direction of the respective component. It should also be understood that in some embodiments, the confinement ring 130 can be made from separate parts, e.g., wherein the tubular extension 132 is separate from the foot extension 134. Further, the first, the second and the third segments (132a, 132b, 132c) can be separate parts. When the confinement ring 130 is made of separate parts, the parts may be connected using mechanical fasteners, glue, screws, and/or the like. In the various confinement ring profiles, a foot extension 134 that extends substantially over the top surface of the edge ring may mean that foot extension 134 extends completely over the top surface of the edge ring 126. Alternatively, a foot extension 134 that extends substantially over the top surface of the edge ring may mean that foot extension 134 extends partially over the top surface of the edge ring (e.g., extends over the inner or outer portion of the edge ring).

In some implementations, the height H1 of the tubular extension 132 of the confinement ring 130 is defined to be between about 20 mm and 65 mm. In still another implementation, the height H1 of the tubular extension 132 is defined to be about 50 mm. In some implementations, the confinement ring 130 is constructed from Aluminum. In some implementations, the confinement ring 130 is made of anodized Aluminum. In some implementations, the confinement ring 130 is coated with a material, such as ALD (Atomic Layer Deposition) Yttria (Yttrium Oxide). In some implementations, the confinement ring is made of a dielectric material, which would not require the use of a ground disconnect 140. In these embodiments, the dielectric material includes any one of Aluminum Oxide (Alumina), Yttria, Quartz, Silicon Nitride, Silicon Carbide, or a combination thereof. The aforementioned list of dielectric materials is provided as a mere example and should not be considered restrictive.

In some implementations, the confinement ring 130 is integrated with the bottom showerhead 106b to create a single piece bottom showerhead with plasma confining capabilities. It should be noted that the design, the dimensions, the material used for defining the confinement ring 130 and of the other components of the process chamber 100 are all provided as examples and should not be considered exhaustive or limiting.

FIG. 3 illustrates a graph of the etch rate in relation to distance from a center of the wafer plotted for an etch operation performed in a process chamber 100 that use a confinement ring 130 with a foot extension 134. Based on testing and experimentation, the various graph lines plotted in the etch rate graph represent different etch profiles for different separations of the gap 136 (i.e., between the top surface of the edge ring 126 and the bottom surface of the foot extension 134 of the confinement ring 130, or between the top surface of the edge ring 126 and the bottom surface of the bottom showerhead). This graph shows that different gaps can assist in tuning the etch performance to remove or reduce etch non-uniformities. While the etch rates near the edge of the wafer will not always be exactly the same as the etch rates at the wafer center, these plots show significant improvement and increased etch rate uniformities near the wafer edge as compared to prior art systems that do not use the confinement ring 130 with the foot extension 134 disclosed in this invention.

For example, graph line 1 shows a baseline etch rate profile extending from the center of the wafer toward the wafer edge of a 300 mm wafer plotted when no confinement ring is present. Graph lines 2-5 represent etch rate profiles when a confinement ring 130 with a foot extension is present and for different gaps defined between a foot extension 134 of the confinement ring 130 and the edge ring 126. Graph line 1 shows etch rate profile when the gap 136 between the top surface of the edge ring 126 and the bottom surface of the lower showerhead is about 37.5 mm. Graph line 2 shows the etch rate when the gap 136 between the top surface of the edge ring 126 and the foot extension 134 of the confinement ring 130 is about 17.7 mm. Graph line 3 shows the etch rate profile when the gap 136 between the top surface of the edge ring 126 and the foot extension 134 of the confinement ring 130 is about 12.7 mm.

Graph line 4 shows the etch rate profile when the gap 136 between the top surface of the edge ring 126 and the foot extension 134 of the confinement ring 130 is about 8.5 mm. Graph line 5 shows a similar etch rate profile as graph line 5 when the gap 136 between the top surface of the edge ring 126 and the foot extension 134 of the confinement ring 130 is about 6.5 mm. Based on the etch rate profiles of the various graph lines shown in the etch rate graph of FIG. 3, to achieve a substantially uniform etch rate at the wafer edge, the gap 136, in some implementations, is defined to be between about 3.5 mm and about 37.5 mm. In some other implementations, to achieve a substantially uniform etch rate at the wafer edge, the gap 136 is defined to be between about 6 mm and about 20 mm. In yet other implementations, the gap 136 is defined to be about 13 mm. As shown, the confinement ring 130 with the foot extension 134 significantly assists in reducing the concentration gradient of radicals at the wafer edge, leading to improvements in etch uniformity across the wafer up to and including the wafer edge.

The foregoing description of the various implementations has been provided for purposes of illustration and description. It is not intended to be exhaustive or to limit the invention. Individual elements or features of a particular implementation are generally not limited to that particular implementation, but, where applicable, are interchangeable and can be used in a selected implementation, even if not specifically shown or described. The same may also be varied in many ways. Such variations are not to be regarded as a departure from the invention, and all such modifications are intended to be included within the scope of the invention.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A confinement ring for use in a process chamber, the confinement ring comprising:
a tubular extension that is configured to surround a process region in the process chamber, the tubular extension having an upper end that is configured to connect to a showerhead disposed in the process chamber and a lower end that is configured to extend proximate to an edge ring, wherein the edge ring is configured to surround a wafer when the wafer is received in the process region for processing; and
a foot extension includes an inner end that joins to the lower end of the tubular extension and extends outwardly from the process region to an outer end, the foot extension defining an annular surface that is configured to form a gap with a top surface of the edge ring, the gap used to flow radicals out from the process region.

2. The confinement ring of claim 1, wherein the tubular extension extends vertically down from the showerhead at a straight angle.

3. The confinement ring of claim 1, wherein the tubular extension extends at an angle that is different from a straight angle of the showerhead, wherein the angle is any one of an acute angle and an obtuse angle in relation to the straight angle.

4. The confinement ring of claim 1, wherein the annular surface of the foot extension is substantially parallel to the top surface of the edge ring.

5. The confinement ring of claim 4, wherein the gap is uniform in height along a width of the foot extension.

6. The confinement ring of claim 1, wherein the foot extension extends substantially perpendicular to the tubular extension.

7. The confinement ring of claim 1, wherein the foot extension extends at a taper angle that is different from a perpendicular angle in relation to the tubular extension, wherein the taper angle is any one of an acute angle and an obtuse angle.

8. The confinement ring of claim 7, wherein the gap varies in height along a width of the foot extension, and
wherein the height of the gap is progressively increasing or decreasing outwardly.

9. The confinement ring of claim 1, wherein a width of the annular surface is equal to a width of the edge ring.

10. The confinement ring of claim 1, wherein a width of the annular surface is greater than or less than a width of the edge ring.

11. The confinement ring of claim 1, wherein a size of the gap is defined to cause an increase in velocity of radicals flowing through the gap and to prevent backflow of radicals.

12. The confinement ring of claim 1, wherein the showerhead includes a top showerhead and a bottom showerhead, and wherein the tubular extension is connected to the bottom showerhead.

13. The confinement ring of claim 1, wherein the confinement ring is integrated into the showerhead.

14. The confinement ring of claim 1, wherein the wafer is received on a top surface of an electrostatic chuck (ESC) defined in a lower portion of the process chamber, and wherein an inner diameter of the confinement ring extends to an outer diameter of the wafer received on the top surface of the ESC, such that the tubular extension aligns with an outer edge of the wafer and the annular surface of the foot extension extends substantially over the top surface of the edge ring.

15. The confinement ring of claim 1, wherein a top surface of the confinement ring includes a groove to receive an O-ring, the O-ring is used to create a seal when the confinement ring is connected to the showerhead.

16. The confinement ring of claim 1, wherein the confinement ring is made of any one of aluminum, anodized aluminum, and aluminum coated with atomic layer deposition (ALD) Yttria or a dielectric material.

17. A process chamber used for etching a wafer, comprising:
an electrostatic chuck (ESC) defined in a lower portion of the process chamber, a top surface of the ESC configured to receive a wafer and an edge ring, the edge ring configured to be disposed adjacent to and surround the wafer;
a plasma chamber defined in an upper portion of the process chamber, the plasma chamber coupled to one or more gas sources to receive process gas(es) and includes one or more coils disposed to surround the plasma chamber, the one or more coils coupled to an RF power source through a matching network to receive RF power, the RF power is used to heat the process gas(es) to generate plasma;
a showerhead defined at a bottom of the plasma chamber, the showerhead having inlets to direct radicals of the plasma toward a process region defined between the showerhead and the ESC of the process chamber,
a confinement ring for use in the process chamber, the confinement ring comprising:
a tubular extension that is configured to surround the process region in the process chamber, the tubular extension having an upper end that is configured to connect to a bottom surface of the showerhead disposed in the process chamber and a lower end that is configured to extend proximate to the edge ring that surrounds the wafer; and
a foot extension with an inner end that joins to the lower end of the tubular extension and extends outwardly from the process region to an outer end, the foot extension defining an annular surface that is configured to form a gap with a top surface of the edge ring, the gap used to flow plasma out from the process region.

18. The process chamber of claim 17, wherein the showerhead includes a top showerhead and a bottom showerhead, and wherein the tubular extension of the confinement ring is connected to the bottom showerhead.

19. The process chamber of claim 17, wherein an inner diameter of the confinement ring extends to an outer diameter of the wafer received on the top surface of the ESC, the tubular extension aligns with an outer edge of the wafer, when the wafer is received on the ESC.

20. The process chamber of claim 17, wherein the tubular extension extends vertically down from the showerhead at a straight angle, and
wherein the annular surface of the foot extension is substantially parallel to the top surface of the edge ring.

21. A confinement ring for use in a process chamber, the confinement ring comprising:
a tubular extension that is configured to surround a process region in the process chamber, the tubular extension having an upper end that is configured to connect to a top plate of the process chamber and a lower end that is configured to extend proximate to an edge ring, wherein the edge ring is configured to surround a wafer when the wafer is received in the process region for processing; and
a foot extension having an inner end that joins to the lower end of the tubular extension and extends outwardly from the process region to an outer end, the foot extension defining an annular surface that is configured to form a gap with a top surface of the edge ring, the gap used to flow plasma out from the process region.
